(19) United States
(12) Patent Application Publication
(10) Pub. No.: US 2024/0203462 A1
(43) Pub. Date: Jun. 20, 2024

(54) DEVICES AND METHODS FOR A FINFET SENSE AMPLIFIER

(71) Applicant: Micron Technology, Inc., Boise, ID (US)

(72) Inventors: Wenjun Li, Meridian, ID (US); Christopher G. Wieduwilt, Boise, ID (US)

(21) Appl. No.: 18/480,130

(22) Filed: Oct. 3, 2023

Related U.S. Application Data
(60) Provisional application No. 63/432,618, filed on Dec. 14, 2022.

(51) Int. Cl. G11C 7/06; G11C 7/08

(52) U.S. Cl. CPC G11C 7/065; G11C 7/08; G11C 2207/002

(57) ABSTRACT

Systems and methods for fabricating various devices with various fin widths in a sense amplifier (SA) of a memory device is described. The various devices in the SA are sensitive to various parameters, which are sensitive to the fin widths of corresponding finFETs. Fabricating various fin widths in the various devices in the SA improves the performance of the memory device. For instance, using thicker fins (greater fin widths) for NMOS sense amplifiers and PMOS sense amplifiers in the SA reduces threshold voltage variations while using thinner fins (smaller fin widths) for control devices in the SA keeps high performance for the control devices.

### CROSS-REFERENCE TO RELATED APPLICATIONS

This application claims priority to U.S. Provisional Application No. 63/432,618, filed Dec. 14, 2022, entitled “DEVICES AND METHODS FOR A FINFET SENSE AMPLIFIER,” the disclosure of which is incorporate by reference in its entirety for all purposes.

### BACKGROUND OF THE INVENTION

### Field of the Invention

The present invention relates generally to the field of memory devices. More specifically, embodiments of the present disclosure relate to non-planar transistors and techniques for fabricating the same in the memory devices.

### Description of the Related Art

This section is intended to introduce the reader to various aspects of art that may be related to various aspects of the present invention, which are described and/or claimed below. This discussion is believed to be helpful in providing the reader with background information to facilitate a better understanding of the various aspects of the present invention. Accordingly, it should be understood that these statements are to be read in this light, and not as admissions of prior art.

Memory devices are widely used to store information related to various electronic devices such as computers, wireless communication devices, cameras, digital displays, and the like. Memory devices are frequently provided as internal memory, integrated circuits and/or external removable devices in computers or other electronic devices. There are many different types of memory, including volatile and non-volatile memory. Volatile memory, including random access memory (RAM), static random access memory (SRAM), dynamic random access memory (DRAM), and synchronous dynamic random access memory (SDRAM), among others, may require a source of applied power to maintain its data. Non-volatile memory, by contrast, may retain its stored data even when not externally powered. Non-volatile memory is available in a wide variety of technologies, including flash memory (e.g., NAND and NOR) phase change memory (PCM), ferroelectric random access memory (FeRAM), resistive random access memory (RRAM), and magnetic random access memory (MRAM), among others.

A memory device may include a number of storage elements, such as memory cells. Memory cells of a binary memory device may, for example, include a charged or discharged capacitor. A charged capacitor of a memory cell may, however, become discharged over time through leakage currents, resulting in the loss of the stored information. Certain features of volatile memory may offer performance advantages, such as faster read or write speeds, while features of non-volatile memory, such as the ability to store data without periodic refreshing, may be advantageous. Some of the memory devices include memory cells that may be accessed by turning on a transistor that couples the memory cell (e.g., the capacitor) with a wordline or a bitline/digit line. Different memory devices may use different architectures for arranging the memory cells. For example, different memory devices may arrange the memory cells in 2-dimensional or 3-dimensional rows and columns. A memory cell may be accessed based on activating a row and a column of the memory device corresponding to the memory cell.

Sense amplifiers (SAs) may be used by a memory device during read operations. Specifically, the read circuitry of the memory device utilizes the sense amplifiers to receive low voltage (e.g., low differential) signals and amplify the small voltage differences to enable the memory device to interpret the data properly. A sense amplifier may include multiple devices (e.g., an isolation gate, a PMOS sense amplifier (PSA), an NMOS sense amplifier (NSA)) formed on an integrated circuit (IC) chip. Fin field effect transistors (finFETs) are often built around a fin (e.g., a tall, thin semiconductive member) extending generally perpendicularly from a substrate. Typically, a gate traverses the fin by conformally running up one side of the fin over the top and down the other side of the fin. Generally, a source and a drain are located on opposite sides of the gate in the fin. In operation, a current through the fin between the source and drain is controlled by selectively energizing the gate. The multiple devices in the SA may be sensitive to various parameters, which may be sensitive to corresponding fin thicknesses. Accordingly, it may be desirable to have various fin thicknesses for the multiple devices in the SA.

### BRIEF DESCRIPTION OF THE DRAWINGS

Various aspects of this disclosure may better be understood upon reading the following detailed description and upon reference to the drawings in which:

FIG. 1 is a block diagram illustrating certain features of a memory device, according to an embodiment of the present disclosure;

FIG. 2 illustrates a memory bank of the memory device of FIG. 1, according to an embodiment of the present disclosure;

FIG. 3 is a circuit diagram for a sense amplifier, according to an embodiment of the present disclosure;

FIG. 4 is a diagram illustrating a fin connecting a source and a drain in a finFET, according to an embodiment of the present disclosure;

FIG. 5 is a top-down view illustrating various devices having various fin widths in a sense amplifier, according to an embodiment of the present disclosure; and

FIG. 6 is a partial cross-sectional view illustrating a process of manufacturing fins for devices in a SA, according to an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

A memory device may perform memory operations such as storing data (e.g., write operations) and retrieving stored data (e.g., read operations). For example, a computing system may include various system components including one or multiple memory devices. The system components may communicate data (e.g., data bits) to perform system operations. For example, the system may include one or more processing components, one or more memory devices, among other system components. In different embodiments, the computing system may be disposed on a single electronic chip or multiple electronic chips. Moreover, the computing system may be disposed on a single electronic device or multiple electronic devices positioned in proximity of or remote from each other.

The memory device may include a number of memory banks, controller circuitry, command decoder circuitry, and a clock circuit to provide the clock signal, among other memory components. In some cases, the controller circuitry (hereinafter, controller) may include the command decoder circuitry (hereinafter, command decoder). In alternative or additional cases, the command decoder may include separate circuitry disposed between the controller and the memory banks or any other viable location. The memory device may include control blocks associated with the memory banks. In some cases, the command decoder may provide the access instructions to the control blocks of the memory banks. The memory banks and/or the control blocks of the memory banks may include sense amplifiers (SAs) used for read operations of the memory device.

The current disclosure herein provides a technology and methods related to fabricating the SAs in memory devices. Various devices in a SA may be sensitive to various parameters, which may be sensitive to the fin thicknesses of corresponding finFETs. Fabricating the various devices in the SA with various fin thicknesses improves the performance of the memory device. For instance, fabricating thicker fins (greater fin widths) for NSAs and PSAs in the SA reduces threshold voltage variations while using thinner fins (smaller fin widths) for control devices in the SA maintains low leakage and keeps high performance for the control devices. Accordingly, the current technology and methods improves signal margin in the SAs as well as area efficiency (AE) in the memory devices.

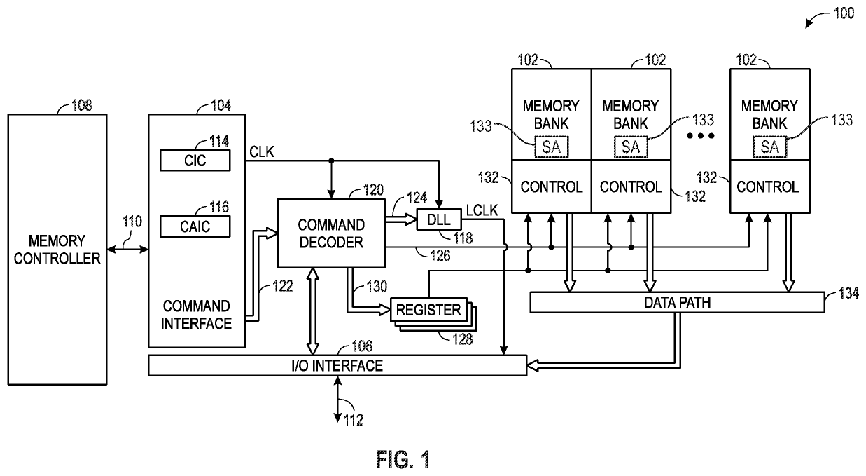

Turning now to the figures, FIG. 1 depicts a simplified block diagram illustrating certain features of a memory device 100 (e.g., a memory subsystem of an apparatus). Specifically, the block diagram of FIG. 1 depicts a functional block diagram illustrating certain functionality of the memory device 100. In accordance with one embodiment, the memory device 100 may include a random access memory (RAM) device, a ferroelectric RAM (FeRAM) device, a dynamic RAM (DRAM) device, a static RAM (SRAM) device (including a double data rate SRAM device), flash memory, and/or a 3D memory array including phase change (PC) memory and/or other chalcogenide-based memory, such as self-selecting memories (SSM). Moreover, each memory cell of such 3D memory array may include a corresponding logic storing device (e.g., a capacitor, a resistor, or the resistance of the chalcogenide material(s)).

The memory device 100 may include a number of memory banks 102 each including one or more memory arrays. Various configurations, organizations, and sizes of the memory banks 102 on the memory device 100 may be used based on an application and/or design of the memory device 100 within an electrical system. For example, in different embodiments, the memory banks 102 may include a different number of rows and/or columns of memory cells. Moreover, the memory banks 102 may each include a number of pins for communicating with other blocks of the memory device 100. For example, each memory bank 102 may receive one data bit per pin at each clock cycle. Furthermore, the memory banks 102 may be grouped into multiple memory groups (e.g., two memory groups, three memory groups).

The memory device 100 may also include a command interface 104 and an input/output (I/O) interface 106. The command interface 104 is configured to provide a number of signals received from a processor (e.g., a processor subsystem of an apparatus) or a controller, such as a memory controller 108. In different embodiments, the memory controller 108, hereinafter controller 108, may include one or more processors (e.g., memory processors), one or more programmable logic fabrics, or any other suitable processing components.

In some embodiments, a bus 110 may provide a signal path or a group of signal paths to allow bidirectional communication between the controller 108, the command interface 104 and the I/O interface 106. For example, the controller 108 may receive memory access requests from the I/O interface via the command interface 104 and the bus 110. Moreover, the controller 108 may provide the access commands and/or access instructions for performing memory operations to the command interface 104 via the bus 110.

Similarly, an external bus 112 may provide another signal path or group of signal paths to allow for bidirectional transmission of signals, such as data signals and access commands (e.g., read/write requests), between the I/O interface 106, the controller 108, a command decoder 120, and/or other components. Thus, the controller 108 may provide various signals (e.g., the access commands, the access instructions, or other signals) to different components of the memory device 100 to facilitate the transmission and receipt of data to be written to or read from the memory banks 102.

That said, the command interface 104 may receive different signals from the controller 108. For example, a reset command may be used to reset the command interface 104, status registers, state machines and the like, during power-up. Various testing signals may also be provided to the memory device 100. For example, the controller 108 may use such testing signals to test connectivity of different components of the memory device 100. In some embodiments, the command interface 104 may also provide an alert signal to the controller 108 upon detection of an error in the memory device 100. Moreover, the I/O interface 106 may additionally or alternatively be used for providing such alert signals, for example, to other system components electrically connected to the memory device 100.

The command interface 104 may also receive one or more clock signals from an external device (e.g., an external clock signal). Moreover, the command interface 104 may include a clock input circuit 114 (CIC) and a command address input circuit 116 (CAIC). The command interface 104 may use the clock input circuit 114 and the command address input circuit 116 to receive the input signals, including the access commands, to facilitate communication with the memory banks 102 and other components of the memory device 100.

Moreover, the clock input circuit 114 may receive the one or more clock signals (e.g., the external clock signal) and may generate an internal clock signal (CLK) therefrom. In some embodiments, the command interface 104 may provide the CLK to the command decoder 120 and an internal clock generator, such as a delay locked loop (DLL) 118 circuit. The DLL 118 may generate a phase controlled internal clock signal (LCLK) based on the received CLK. For example, the DLL 118 may provide the LCLK to the I/O interface 106. Subsequently, the I/O interface 106 may use the received LCLK as a clock signal for transmitting the read data using the external bus 112.

The command interface 104 may also provide the internal clock signal CLK to various other memory components. As mentioned above, the command decoder 120 may receive the internal clock signal CLK. In some cases, the command decoder 120 may also receive the access commands via a bus 122 and/or through the I/O interface 106 received via the external bus 112. For example, the command decoder 120 may receive the access commands through the I/O interface 106 transmitted by one or more external devices. In some cases, a processor may transmit the access commands.

The command decoder 120 may decode the access commands and/or the memory access requests to provide corresponding access instructions for accessing target memory cells. For instance, the command decoder 120 may provide the access instructions to one or more control blocks 132 associated with the memory banks 102 via a bus path 126. In some cases, the command decoder 120 may provide the access instructions to the control blocks 132 in coordination with the DLL 118 over a bus 124. For example, the command decoder 120 may coordinate generation of the access instructions in-line (e.g., synchronized) with the CLK and/or LCLK. In some cases, the command decoder 120 may receive the access commands using a rising edge and/or a falling edge of the external clock signal. For example, a processor may transmit the access commands using a memory command protocol, such as a single clock cycle memory command protocol, or a multi-clock cycle memory command protocol. The processor may use a specific memory command protocol based at least in part on the number of pins of the memory device 100 or the I/O interface 106, the number of rows and/or columns of the memory banks 102, and the number of memory banks 102. Subsequently, the command decoder 120 may provide the access instructions to the memory banks 102 based on receiving and decoding the access commands.

Accordingly, the command decoder 120 may provide the access instructions to the memory banks 102 using one or multiple clock cycles of the CLK via the bus path 126. The command decoder 120 may also transmit various signals to one or more registers 128 via, for example, one or more global wiring lines 130. Moreover, the memory device 100 may include other decoders, such as row decoders and column decoders, to facilitate access to the memory banks 102, as discussed below.

In some embodiments, each memory bank 102 may include a respective control block 132. In some cases, each of the control blocks 132 may also provide row decoding and column decoding capability based on receiving the access instructions. Accordingly, the control block 132 may facilitate accessing the memory cells of the respective memory banks 102. For example, the control blocks 132 may include circuitry (e.g., logic circuitry) to facilitate accessing the memory cells of the respective memory banks 102 based on receiving the access instructions. For example, each memory bank 102 and/or corresponding control block 132 may include sense amplifiers 133 for read operations of the memory cells of respective memory bank 102.

In some cases, the control blocks 132 may receive the access instructions and determine target memory banks 102 associated with the target memory cells. In specific cases, the command decoder 120 may include the control blocks 132. Moreover, the control blocks 132 may also provide timing control and data control functions to facilitate execution of different commands with respect to the respective memory banks 102.

Furthermore, the command decoder 120 may provide register commands to the one or more registers 128 to facilitate operations of one or more of the memory banks 102, the control blocks 132, and the like. For example, one of the one or more registers 128 may provide instructions to configure various modes of programmable operations and/or configurations of the memory device 100. The one or more registers 128 may be included in various memory devices to provide and/or define operations of various components of the memory device 100.

In some embodiments, the one or more registers 128 may provide configuration information to define operations of the memory device 100. For example, the one or more registers 128 may include operation instructions for DRAMs, synchronous DRAMs, FeRAMs, chalcogenide memories (e.g., SSM memory, PC memory), or other types of memories. As discussed above, the one or more registers 128 may receive various signals from the command decoder 120, or other components, via the one or more global wiring lines 130.

In some embodiments, the one or more global wiring lines 130 may include a common data path, a common address path, a common write command path, and a common read command path. The one or more global wiring lines 130 may traverse across the memory device 100, such that each of the one or more registers 128 may couple to the global wiring lines 130. The additional registers may involve additional wiring across the memory device (e.g., die), such that the registers are communicatively coupled to the corresponding memory components.

The I/O interface 106 may include a number of pins (e.g., 7 pins) to facilitate data communication with external components (e.g., the processing component, such as a processor). Particularly, the I/O interface 106 may receive the access commands via the pins. Moreover, data stored on the memory cells of the memory banks 102 may be transmitted to and/or retrieved from the memory banks 102 over a data path 134. The data path 134 may include a plurality of bi-directional data buses to one or more external devices via the I/O interface 106. For certain memory devices, such as a DDR5 SDRAM memory device, the I/O signals may be divided into upper and lower bytes; however, such segmentation is not utilized in conjunction with other memory device types.

That said, in different embodiments, the memory device 100 may include additional or alternative components. That is, the memory device 100 may include additional or alternative components such as power supply circuits (for receiving external VDD and VSS signals), read/write amplifiers (to amplify signals during read/write operations), temperature sensors (for sensing temperatures of the memory device 100), etc. Accordingly, it should be understood that the block diagram of FIG. 1 is only provided to highlight certain functional features of the memory device 100 to aid in the subsequent detailed description.

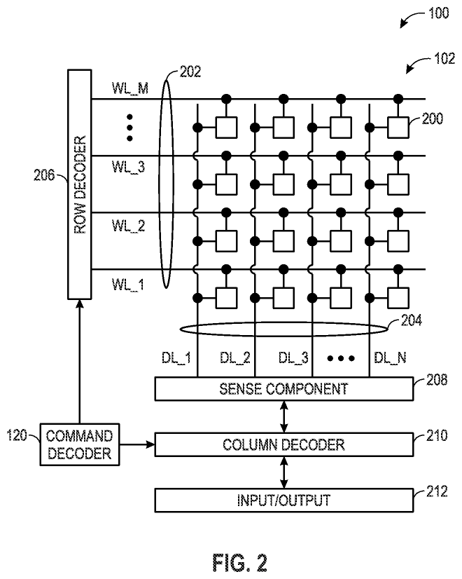

Referring now to FIG. 2, a memory bank 102 of the memory device 100 is illustrated in accordance with various examples of the present disclosure. The memory bank 102 may include a number of memory cells 200 that are programmable to store different memory states. In the depicted embodiment, the memory cells 200 may be arranged in multiple rows (e.g., 22 rows, 19 rows, etc.) and multiple columns.

Memory operations, such as reading and writing memory states, may be performed on the memory cells 200 by activating or selecting the appropriate word lines 202 and digit lines 204. Activating or selecting a word line 202 or a digit line 204 may include applying a voltage to the respective lines. The word lines 202 and the digit lines 204 may include conductive materials.

For example, word lines 202 and digit lines 204 may be made of metals (such as copper, aluminum, gold, tungsten, etc.), metal alloys, other conductive materials, or the like. In the depicted embodiment, each row of the memory cells 200 is connected to a single word line 202, and each column of the memory cells 200 is connected to a single digit line 204. Moreover, each of the memory cells 200 may be associated with a row and a column of the memory bank 102. Accordingly, each of the memory cells 200 is connected to a respective word line 202 and a respective digit line 204.

By applying a voltage to a single word line 202 and a single digit line 204, a single memory cell 200 may be activated (or accessed) at their intersection. Accessing the memory cell 200 may include performing reading or writing operation on the memory cell 200. For example, a read operation may include sensing a charge level from the memory cell 200. The intersection of a word line 202 and digit line 204 may be referred to as an address of a respective memory cell 200. Accordingly, the command decoder 120 may provide the access instructions, including the address bits, to indicate the word lines 202 and digit lines 204 corresponding to the target memory cells 200.

In some architectures, the memory state storage of the memory cell 200 (e.g., a capacitor) may be electrically isolated from the digit line by a selection component. The word line 202 may be connected to and may control the selection component. For example, the selection component may be a transistor and the word line 202 may be connected to the gate of the transistor. Activating the word line 202 may result in an electrical connection or closed circuit between the capacitor of the memory cell 200 and its corresponding digit line 204. The digit line 204 may then be activated to either read or write the memory cell 200.

Accordingly, accessing the memory cell 200 may be controlled through a respective row decoder 206 and a respective column decoder 210. As mentioned above, in different embodiments, the controller 108, the command decoder 120, and/or the control blocks 132 may include the row decoder 206 and/or the column decoder 210. In some examples, the row decoder 206 may receive a row address from the command decoder 120 and may activate the appropriate word line 202 based on the received row address.

Similarly, a column decoder 210 may receive a column address from the command decoder 120 and may activate the appropriate digit line 204. The command decoder 120 may provide the row address and the column address based on receiving and decoding the access commands and providing the access instructions. For example, the memory bank. 102 may include multiple word lines 202, labeled WL_1 through WL M, and multiple digit lines 204, labeled DL_1 through DL_N, where M and N depend on the array size. Thus, by activating a word line 202 and a digit line 204, e.g., WL_2 and DL_3, the memory cell 200 at their intersection may be accessed.

In any case, upon accessing, the memory cell 200 may be read, or sensed, by a sense component 208 (e.g., includes one or more sense amplifiers 133) to determine the stored state of the memory cell 200. For example, after accessing the memory cell 200, a ferroelectric capacitor of the memory cell 200 may discharge a first charge (e.g., a dielectric charge) onto its corresponding digit line 204. In other examples, after accessing the memory cell 200, the ferroelectric capacitor of the memory cell 200 may discharge a second or third charge (e.g., a polarization charge) onto its corresponding digit line 204. Discharging the ferroelectric capacitor may be based on biasing, or applying a voltage, to the ferroelectric capacitor.

The discharging may induce a change in the voltage of the digit line 204, which sense component 208 may compare to a reference voltage (not shown) in order to determine the stored state of the memory cell 200. For example, if the digit line 204 has a higher voltage than the reference voltage, then sense component 208 may determine that the stored state in the memory cell 200 is related to a first predefined memory state. In some cases, the first memory state may include a state 1, or may be another value—including other logic values associated with multi-level sensing that enables storing more than two values (e.g., 3 states per cell or 1.5 bits per cell). The sense component 208 may include various transistors or amplifiers in order to detect and amplify a difference in the signals, which may be referred to as latching. The detected logic state of the memory cell 200 may then be output through column decoder 210 as output 212.

In some examples, detecting and amplifying a difference in the signals may include latching a charge that is sensed in sense component 208. One example of this charge may include latching a dielectric charge associated with the memory cell 200. As an example, the sense component 208 may sense a dielectric charge associated with the memory cell 200. The sensed dielectric charge may be latched in a latch within the sense component 208 or a separate latch that is in electronic communication with the sense component 208.

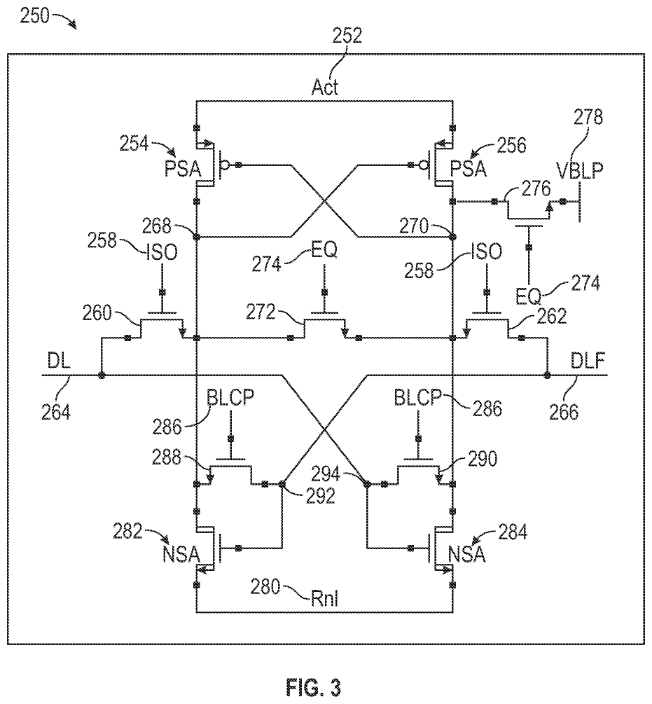

FIG. 3 is a circuit diagram of a sense amplifier 250 that may be implemented as an embodiment of the sense amplifiers 133 of FIG. 1. Although only a single sense amplifier 250 is shown in FIG. 3, multiple sense amplifiers 133 are included in the memory device 100 that may share at least some control signals and/or supply voltages.

As illustrated, the sense amplifier 250 receives an activate signal (ACT) 252 as a local voltage. The ACT 252 activates the sense amplifier 250 by providing an operating voltage to the sense amplifier 250. In particular, the ACT 252 is coupled to respective PMOS (p-channel metal-oxide semiconductor) transistors in a PMOS sense amplifier (PSA) 254 and a PMOS sense amplifier (PSA) 256, respectively. In the current disclosure, terms PSA 254 and PSA 256 are referred to herein as the respective PMOS transistor in the corresponding PSA. The sense amplifier 250 also receives an isolation signal (ISO) 258, which is used by transistors 260 and 262 to couple and decouple internal circuitry of the sense amplifier 250 from respective digit lines (DL) 264 and (DLF) 266. The digit line (DL) 264 may be indicative of the data in the memory cell as a “bit line true” signal (BLT) while the digit line (DLF) 266 may be opposite as a complementary “bit line bar/false” signal (BLB). The transistors 260 and 262 are coupled to the PSAs 254 and 256 at gut nodes 268 and 270, respectively. Thus, the ISO 258 controls coupling of the gut node 268 to and decoupling of the gut node 268 from the digit line (DL) 264 via the transistor 260. Similarly, the ISO 258 controls coupling of the gut node 270 to and decoupling of the gut node 270 from the digit line (DLF) 266 via the transistor 262. Gut nodes 268 and 270 are each coupled to a respective first terminal (e.g., gate) of one of the PSAs 254 and 256 and a respective second terminal (e.g., drain) of the other of the PSAs 254 and 256.

Accordingly, when a voltage difference between the DL 264 and DLF 266 is greater than a threshold voltage Vth-1 of the transistors in the PSA 254 and PSA 256, one of the PSA 254 and the PSA 256 may be turned on and the other one may be turned off. For example, when the SA 250 is activated by the ACT 252 and the transistors 260 and 262 are turned on by the ISO 258, if the voltage on the DL 264 is higher than the voltage on the DLF 266 by at least the threshold voltage Vth-1, then the voltage at the gut node 268 is higher than the voltage at the gut node 270 by at least the threshold voltage Vth-1, and the PSA 254 is turned on due to the voltage at the gut node 270, which is connected to the gate of the PSA 254, is lower than the voltage at the gut node 268, which is connected to the drain of the PSA 254, by at least the threshold voltage Vth-1. In the example above, the PSA 256 is turned off due to the voltage at the gut node 268, which is connected to the gate of the PSA 256, is higher than the voltage at the gut node 270, which is connected to the drain of the PSA 256. Similarly, when the voltage on the DLF 266 is higher than the voltage on the DL 264 by at least the threshold voltage Vth-1, the PSA 256 is turned on and the PSA 254 is turned off. When either the PSA 254 or the PSA 256 is turned on, the voltage difference between the DL 264 and DLF 266 may be amplified.

The sense amplifier 250 further includes a transistor 272, which is used to equalize the voltages of the gut nodes 268 and 270 based on an equalization signal (EQ) 274. In addition, the sense amplifier 250 includes a transistor 276 coupled to the gut node 270 so that the gut node 270 may be discharged/charged to a bit line precharge voltage (VBLP) 278 via the transistor 276 when the EQ 274 is asserted.

The sense amplifier 250 further receives an RNL (row Nsense latch signal) signal 280. The RNL signal 280 is coupled to respective NMOS (n-channel metal-oxide semiconductor) transistors in an NMOS sense amplifier (NSA) 282 and an NMOS sense amplifier (NSA) 284, respectively. In the current disclosure, terms NSA 282 and NSA 284 are referred to herein as the respective NMOS transistor in the corresponding NSA. The SA 250 further receives a bit line compensation enable signal (BLCP) 286, which is coupled to respective gates of a transistor 288 and a transistor 290, respectively. The transistor 288 is coupled to the DLF 266 via a sense node 292, and the transistor 290 is coupled to the DL 264 via a sense node 294. Sense nodes 292 and 294 are each coupled to a respective first terminal (e.g., gate) of one of the NSAs 282 and 284 and a respective second terminal (e.g., drain) of one of the transistors 288 and 290. A respective second terminal (e.g., drain) of the NSA 282 is coupled to the gut node 268, and a respective second terminal (e.g. drain) of the NSA 284 is coupled to the gut node 270. Thus, the BLCP 286 controls coupling of the NSA 282 to and decoupling of the NSA 282 from the DLF 266 via the transistor 288. Similarly, the BLCP 286 controls coupling of the NSA 284 to and decoupling of the NSA 284 from the DL 264 via the transistor 290.

Accordingly, when a voltage difference between the DL 264 and DLF 266 is greater than a threshold voltage Vth-2 of the transistors in the NSA 282 and NSA 284, one of the NSA 282 and the NSA 284 may be turned on and the other one may be turned off. For example, when the NSA 282 and the NSA 284 are activated by the RNL signal and the transistors 288 and 290 are turned off by the BLCP 286, if the voltage on the DL 264 is higher than the voltage on the DLF 266 by at least the threshold voltage Vth-2, then the voltage at the sense node 294 is higher than the voltage at the gut node 270 by at least the threshold voltage Vth-2, and the NSA 284 is turned on due to the voltage at the sense node 294, which is connected to the gate of the NSA 284, is higher than the voltage at the gut node 270, which is connected to the drain of the NSA 284, by at least the threshold voltage Vth-2. In the example above, the NSA 282 is turned off due to the voltage at the sense node 292, which is connected to the gate of the NSA 282, is lower than the voltage at the gut node 268, which is connected to the drain of the NSA 282. Similarly, when the voltage on the DLF 266 is higher than the voltage on the DL 264 by at least the threshold voltage Vth-2, the NSA 282 is turned on and the NSA 284 is turned off. When either the NSA 282 or the NSA 284 is turned on, the voltage difference between the DL 264 and DLF 266 may be amplified.

As described above, threshold voltages (e.g., Vth-1, Vth-2) of PSAs and NSAs in the SA 250 are of important roles in the operation of the SA 250. To improve the performance of the SA 250, a smaller threshold voltage variation of a threshold voltage (e.g., Vth-1, Vth-2) is desirable. In a finFET, a fin (e.g., a tall, thin semiconductive member) extends generally perpendicularly from a substrate, and a gate traverses the fin by conformally running up one side of the fin over the top and down the other side of the fin with a source and a drain located on opposite sides of the gate. In operation, a current through the fin between the source and drain is controlled by selectively energizing the gate. Thus, the threshold voltage of a finFET may be varied according to a variation of the fin width (e.g., gate edge roughness). Accordingly, the fin width of the finFET may be designed to reduce the variation of the threshold voltage of the finFET.

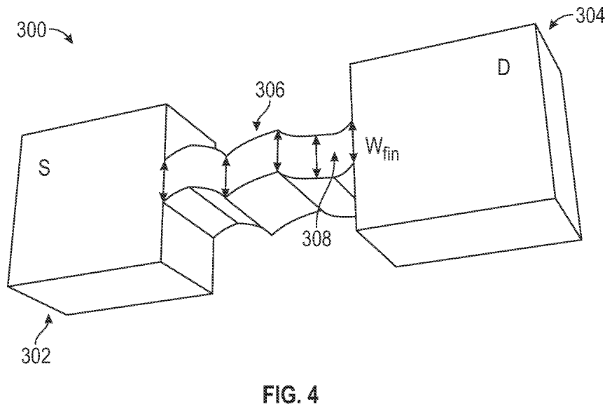

FIG. 4 is a diagram illustrating a finFET 300 having a source 302 and a drain 304 connected by a fin 306. As illustrated in FIG. 4, a fin width 308 (W_{fin}) may vary along the length of the fin 306 in the finFET 300 due to fin edge roughness resulted from an etch process used to form the fin. A threshold voltage Vt of the finFET 300 is associated with the fin width 308, and a variation of the threshold voltage ΔVt is associated with the fin width 308 and a variation of the fin width ΔW_{fin}. When the variation of the fin width ΔW_{fin}, is fixed (e.g., due to the etching technology used for fabricating the finFET), the variation of the threshold voltage ΔVt is of inverse correlation with the value of the fin width 308. Thus, the variation of the threshold voltage ΔVt is smaller when the fin width 308 is bigger. Accordingly, the fin width 308 of the finFET 300 may be increased in order to reduce the variation of the threshold voltage of the finFET 300.

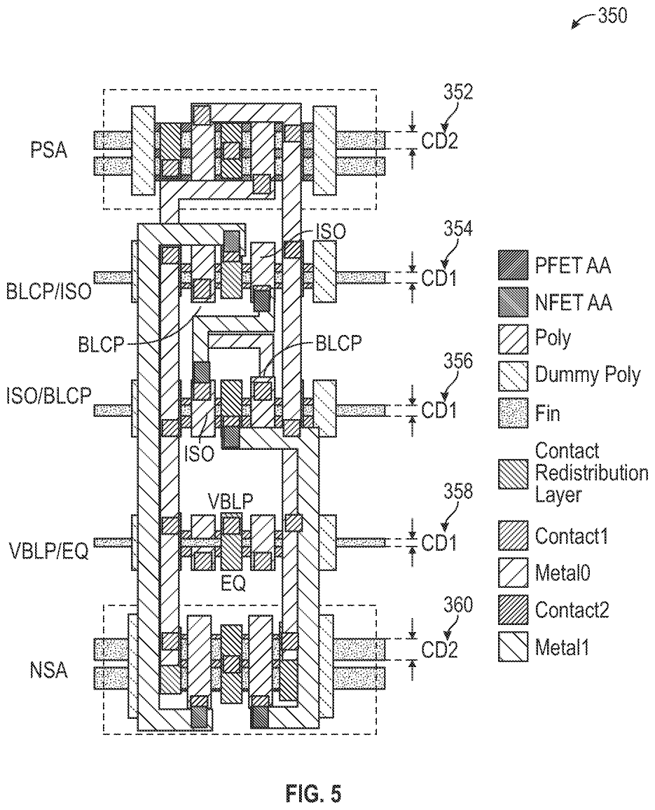

At the same time, a transistor saturated drive current Idsat and a leakage current Idoff of the finFET 300 are also associated with the fin width 308. For instance, control devices in SA 250 (e.g., the transistors 260 and 262 associated with the signal ISO 258, the transistors 272 and 276 associated with the signal EQ 274, the transistors 288 and 290 associated with the signal BLCP 286) may be benefit from thinner fin width to maintain low leakage and high performance. Accordingly, fabricating the various devices in the SA with various fin thicknesses improves the performance of the memory device. For instance, fabricating thicker fins (greater fin widths) for the NSAs and PSAs in the SA reduces variations of the threshold voltages while using thinner fins (smaller fin widths) for control devices in the SA maintains low leakage and keeps high performance for the control devices, as illustrated in FIG. 5.

FIG. 5 illustrates various devices in a SA having various fin widths in a non-rotated SA structure 350. FIG. 5 illustrates a number of features and materials deposited and patterned on a substrate and that may be included in the SA structure 350, as will be appreciated by those skilled in the art. For instance, as illustrated, the SA structure 350 may include PFET AA (p-channel field effect transistor active area), NFET AA (n-channel field effect transistor active area), Poly (polysilicon), Dummy Poly, contact redistribution layer (or contact routing layer), Contact1 (contact layer 1), Metal0, Contact2 layer (contact layer 2), and Metal1. Fins are also illustrated in the SA structure 350.

In the non-rotated SA structure 350 in FIG. 5, the PSAs (e.g., the PSAs 254 and 256) have a fin width 352; the devices associated with the signal ISO 258 (e.g., the transistors 260 and 262) or the signal BLCP 286 (e.g., the transistors 288 and 290) have a fin width 354 or a fin width 356; the devices associated with the signal VBLP 278 (e.g., the transistor 276) or the signal EQ 274 (e.g., the transistors 272 and 276) have a fin width 358; and the NSAs (e.g., the NSAs 282 and 284) have a fin width 360. In the embodiment illustrated in FIG. 5, the fin widths 352 and 360 have the same value of CD2, and the fin widths 354, 356, and 358 have the same value of CD1, with CD2>CD1. In other embodiment, the fin widths 352 and 360 may have different values and/or the fin widths 354, 356, and 358 may have different values. In the embodiment illustrated in FIG. 5, only two fin widths (e.g., CD1 and CD2) are used, however, more than two fin widths may be used for various devices in a SA in other embodiment.

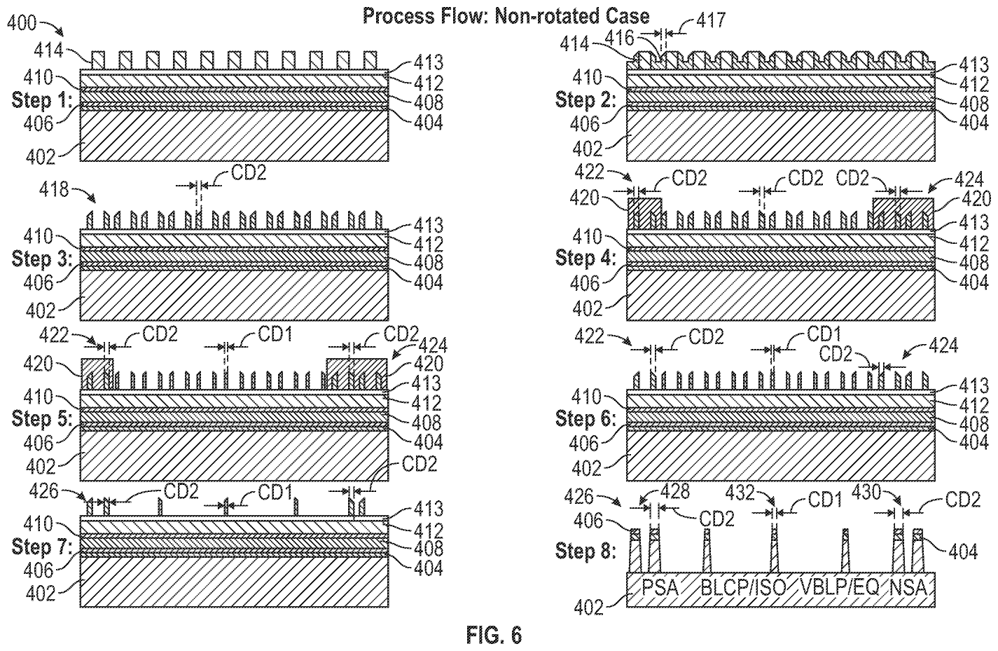

FIG. 6 illustrates a cross-sectional view of a process 400 for fabricating the various devices in the non-rotated SA structure 350 using the various fin widths (e.g., CD1, CD2) shown in FIG. 5. The illustrated process 400 includes steps 1-8, for instance. As will be appreciated, the illustrated process 400 is provided only to highlight certain features described in accordance with embodiments of the invention. In one embodiment, the structures illustrated in the process 400 includes a base substrate 402, such as a silicon substrate, and various substrate layers 404, 406, 408, 410, 412, and 413 formed thereon. The combination of the various substrate layers may be referred to as a hard mask stack, and any substrate layer may be one of an oxide layer, a nitride layer and a carbon layer, for instance. In some embodiments, the hard mask stack may include more substrate layers or less substrate layers than the one that is illustrated in FIG. 6.

At step 1 of the process 400, a material layer, such as carbon layer, may be deposited and patterned to form a hard-mask layer 414 including mandrel features on top of the substrate layer 413 which may be used to fabricate the various fins described above. At step 2 of the process 400, a spacer layer 416 may be deposited over the patterned hard-mask mandrel layer 414 with a thickness 417, which is greater than that which may be generally used in the process of records (POR) (e.g., CD1). At step 3 of the process 400, a material removal process (e.g., dry etch) may be used to remove the hard-mask mandrel layer 414 and trim the spacer layer 416 to form a set of uniform fins 418 with a fin width CD2 (CD2>CD1). At step 4 of the process 400, a set of hard masks 420 may be used to protect a set of the uniform fins 418 in the regions 422 and 424, which are designed to form PSAs and NSAs in the SA structure 350, respectively, so that the set of uniform fins 418 in the protected regions 422 and 424 may not be etched/trimmed in step 5. At step 5 of the process 400, another material removal process (e.g., dry etch) may be used to trim the thickness of the uniform fins 418 in the exposed area, which are not protected by the set of hard masks 420, from CD2 to CD1. At step 6 of the process 400, the set of hard-masks 420 are removed from the protected regions 422 and 424 (e.g., via wet etch). Now two groups of fins with different widths exist on the substrate layer 413, with one group of fins having a common width of CD1 and one group of fins having a common width of CD2. At step 7 of the process 400, an active area (AA) 426 of the SA structure 350 may be defined, and fins that are not in the active area (AA) 426 may be removed. At step 8 of the process 400, another dry etch method may be used to form the PSAs using one or more fins 428 with width CD2, the NSAs using one or more fins 430 with width CD2, and control devices (e.g., devices associated with BLCP/ISO or VBLP/EQ) in the SA structure 350 using one or more fins 432 with width CD1.

In the embodiment illustrated in FIG. 6, a non-rotated SA structure is used. However, in other embodiments, other SA structures, such as a rotated SA structure, may be used. Moreover, although the embodiment in FIG. 6 illustrates a method to form two groups of fins with two fin widths (e.g., CD1 and CD2), more than two groups of fins with different fin widths may be formed. For example, extra steps may be inserted after the step 5 and before the step 6 to use a second set of hard masks to protect one or more trimmed fins, which have a thickness of CD1, and then trim the fins left in the exposed area (i.e., outside of the first set of hard masks and outside of the second set of hard masks) to have a thickness CD3, with CD3<CD1. In the example described above, three groups of fins with different fin widths (e.g., CD1, CD2, CD 3, with CD2>CD1>CD3) may be formed. Accordingly, more groups of fins with different fin widths may be formed by extra steps and by using more sets of hard masks.

In the illustrated embodiments above, the memory devices and systems are primarily described in the context of devices incorporating DRAM storage media. Memory devices configured in accordance with other embodiments of the present technology, however, may include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. A device, comprising:
a first component comprising a first fin field effect transistor (finFET), wherein the first finFET comprises a first fin with a first width; and
a second component comprising a second finFET, wherein the second finFET comprises a second fin with a second width, wherein the first width is greater than the second width, and wherein the first component is configured to detect a voltage difference between two signals.

2. The device of claim 1, wherein the first component comprises a PMOS sense amplifier (PSA), and wherein the PSA comprises the first finFET.

3. The device of claim 2, wherein the first component comprises an NMOS sense amplifier (NSA), wherein the NSA comprises a third finFET, and wherein the third finFET comprises a third fin with the first width.

4. The device of claim 2, wherein the first component comprises an NMOS sense amplifier (NSA), wherein the NSA comprises a third finFET, and wherein the third finFET comprises a third fin with a third width, and wherein the third width is greater than the second width.

5. The device of claim 1, wherein the first component comprises an NMOS sense amplifier (NSA), and wherein the NSA comprises the first finFET.

6. The device of claim 1, comprising a third finFET, wherein the third finFET comprises a third fin with a third width.

7. The device of claim 1, wherein one of the two signals is received from a digit line and the other of the two signals is a reference voltage.

8. The device of claim 1, wherein the two signals are received from respective digit lines in a memory device.

9. A circuit, comprising:
a first fin field effect transistor (finFET), wherein the first finFET is configured to receive a first signal and a second signal and detect a voltage difference between the first signal and the second signal; and
a second finFET, wherein the first finFET comprises a first fin with a first width and the second finFET comprises a second fin with a second width, and wherein the first width is greater than the second width.

10. The circuit of claim 9, wherein the circuit further comprises a third finFET, wherein the third finFET comprises a third fin with a third width, wherein the third width is greater than the second width.

11. The circuit of claim 9, wherein the first finFET is comprised in a PMOS sense amplifier (PSA).

12. The circuit of claim 9, wherein the first finFET is comprised in an NMOS sense amplifier (NSA).

13. The circuit of claim 9, wherein the first signal is received from a first digit line in a memory device and the second signal is receive from a second digit line in the memory device.

14. A method, comprising:
forming a plurality of fins on a substrate, wherein the plurality of fins have a common first fin width;
covering one or more fins of the plurality of fins using one or more hard masks;
trimming a set of fins of the plurality of fins to have a common second fin width, wherein the set of fins is located outside of the one or more hard masks; and
forming a first device comprising a first fin having the first fin width and forming a second device comprising a second fin having the second fin width, wherein the first device comprises a sense amplifier.

15. The method of claim 14, wherein the sense amplifier comprises a PMOS sense amplifier (PSA).

16. The method of claim 14, wherein the sense amplifier comprises an NMOS sense amplifier (NSA).

17. The method of claim 14, wherein the second device comprises a control device configured to activate the first device to detect a voltage difference between two signals.

18. The method of claim 17, wherein the first fin width is greater than the second fin width.

19. The method of claim 18, wherein the two signals are received from two digit lines of a memory device.

20. The method of claim 14, further comprising:
covering one or more fins of the set of fins having the common second fin width using a set of hard masks;
trimming a subset of fins of the set of fins to have a common third fin width, wherein the subset of fins is located outside of the set of hard masks; and
forming a third device comprising a third fin having the third fin width.
